(19) United States
(12) Patent Application Publication
(10) Pub. No.: US 2023/0167551 A1
(43) Pub. Date: Jun. 1, 2023

(54) OZONE SUPPLY SYSTEM, SUBSTRATE PROCESSING APPARATUS, AND OZONE SUPPLY METHOD

(71) Applicant: Tokyo Electron Limited, Tokyo (JP)

(72) Inventor: Eiichi KOMORI, Aichi (JP)

(21) Appl. No.: 18/055,893

(22) Filed: Nov. 16, 2022

(30) Foreign Application Priority Data
Nov. 30, 2021 (JP) 2021-194791

(51) Int. Cl. C23C 16/455; C23C 16/52; C23C 16/40

(52) U.S. Cl. CPC C23C 16/45561; C23C 16/52; C23C 16/405; C23C 16/45544; C23C 16/45565; H01L 21/02181

(57) ABSTRACT

An ozone supply system includes a supply path configured to supply a gas, and an ozone generator, provided in the supply path, and configured to generate ozone using oxygen gas supplied from an upstream end of the supply path, and supply an ozone-containing gas containing the ozone to a downstream end of the ozone generator. The supply path branches into a plurality of branching paths on the downstream end. At least one branching path of the plurality of branching paths is a process branching path connected to a processing part that uses the ozone-containing gas, and a remaining branching path, other than the at least one branching path, of the plurality of branching paths is a waste branching path connected to a waste part configured to discharge the ozone-containing gas. The waste branching path includes a waste flow controller configured to control a flow rate of the ozone-containing gas.

### CROSS-REFERENCE TO RELATED APPLICATIONS

This application is based upon and claims priority to Japanese Patent Application No. 2021-194791, filed on Nov. 30, 2021, the entire contents of which are incorporated herein by reference.

### BACKGROUND

### 1. Field of the Invention

The present disclosure relates to ozone supply systems, substrate processing apparatuses, and ozone supply methods.

### 2. Description of the Related Art

A substrate processing apparatus may use ozone (O₃), as a process gas, when performing oxidation, etching, or the like of a substrate inside a process chamber. In this case, an ozone supply system is connected to the process chamber. The ozone supply system includes an ozone generator that generates the ozone by performing a discharge with respect to oxygen (O₂).

Further, in recent years, an ozone supply system has been developed for supplying the ozone from a single ozone generator to a plurality of process chambers, in order to reduce manufacturing cost and footprint. For example, Japanese Laid-Open Patent Publication No. 2005-126267 proposes a technique for stabilizing the ozone supply, by varying a discharge output of the ozone generator according to a variation in a flow rate of a source gas, when supplying the ozone from the single ozone generator to the plurality of process chambers.

### SUMMARY

One object according to one aspect of the present disclosure is to provide a technique for stabilizing generation of ozone in an ozone generator.

According to one aspect of the present disclosure, there is provided an ozone supply system including a supply path configured to supply a gas; and an ozone generator, provided in the supply path, and configured to generate ozone using oxygen gas supplied from an upstream end of the supply path, and supply an ozone-containing gas containing the ozone to a downstream end of the ozone generator, wherein the supply path branches into a plurality of branching paths on the downstream end of the ozone generator, at least one branching path of the plurality of branching paths is a process branching path connected to a processing part that uses the ozone-containing gas, a remaining branching path, other than the at least one branching path, of the plurality of branching paths is a waste branching path connected to a waste part configured to discharge the ozone-containing gas, and the waste branching path includes a waste flow controller configured to control a flow rate of the ozone-containing gas.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a schematic diagram illustrating an ozone supply system according to one embodiment;

FIG. 2 is a schematic cross sectional view illustrating a substrate processing apparatus provided with an ozone supply system;

FIG. 3 is a block diagram illustrating functional blocks of a controller of the ozone supply system;

FIG. 4A is a diagram for explaining an operation of the ozone supply system according to one embodiment;

FIG. 4B is a diagram for explaining an operation of an ozone supply system according to a reference example;

FIG. 5 is a flow chart illustrating an ozone supply method of the ozone supply system; and

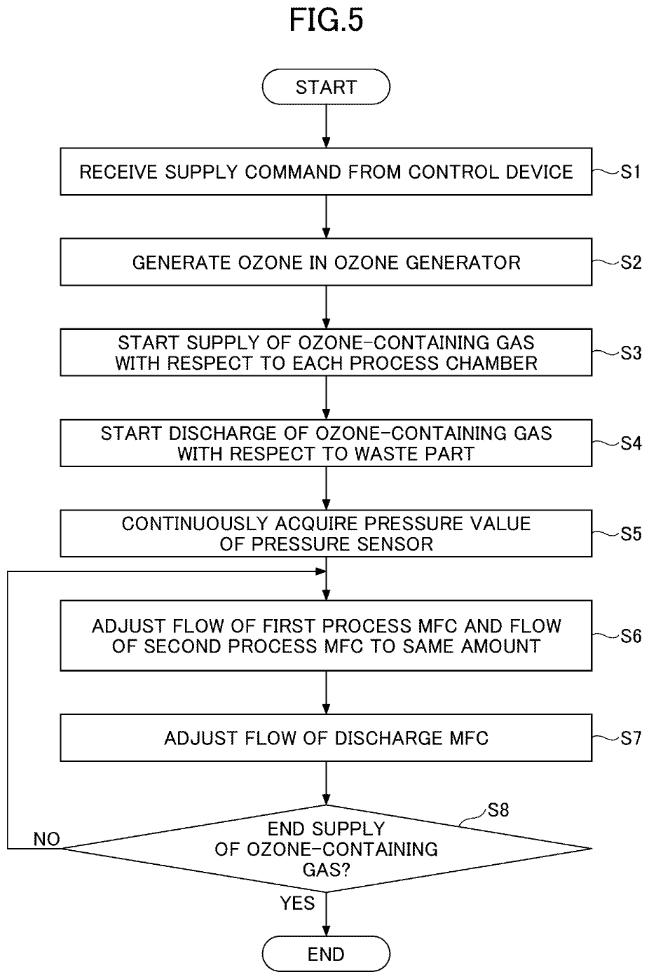

FIG. 6 is a schematic diagram illustrating the ozone supply system according to a modification.

### DETAILED DESCRIPTION

Hereinafter, embodiments of the present disclosure will be described with reference to the drawings. In the drawings, the same constituent elements are denoted by the same reference numerals, and a repeated description of the same constituent elements may be omitted.

[Configuration of Ozone Supply System]

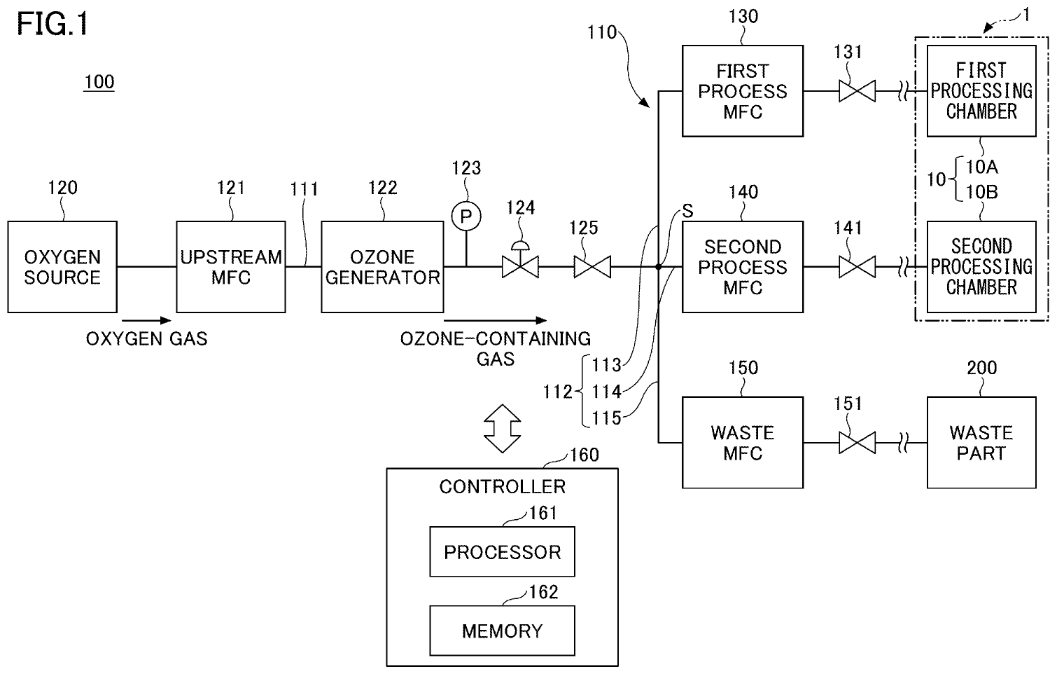

As illustrated in FIG. 1, an ozone supply system 100 according to one embodiment is provided in a substrate processing apparatus 1, and supplies an ozone-containing gas, containing ozone (03), to a process chamber 10 that is a supply target. In addition, the ozone supply system 100 according to the present embodiment can supply the ozone-containing gas to a plurality of process chambers 10 (two process chambers 10 in the example illustrated in FIG. 1) of the substrate processing apparatus 1. In the following description, the two process chambers 10 of the substrate processing apparatus 1 may also be referred to as a first process chamber 10A and a second process chamber 10B when distinguishing the two process chambers 10.

The ozone supply system 100 includes a supply path 110 for supplying the ozone-containing gas to each process chamber 10. The supply path 110 can be famed by connecting a plurality of pipes provided with a corrosion resistant coating or the like, for example. The supply path 110 branches to supply the ozone-containing gas to the first process chamber 10A, the second process chamber 10B, and a waste part 200, respectively. More particularly, the supply path 110 includes one common path 111, and branching paths 112 branching from a branch point S on a downstream end of the common path 111. The branching paths 112 include a first process branching path 113, a second process branching path 114, and a waste branching path 115.

The first process branching path 113 is connected to the first process chamber 10A, and supplies the ozone-containing gas to the first process chamber 10A. The second process branching path 114 is connected to the second process chamber 10B, and supplies the ozone-containing gas to the second process chamber 10B. The waste branching path 115 is connected to the waste part 200 for processing an exhaust gas, and discards the ozone-containing gas as waste. As described above, the ozone supply system 100 has a number of branching paths 112, that is one greater than the number of the process chambers 10 that are supply targets of the ozone-containing gas, thereby stabilizing the supply of the ozone-containing gas.

More particularly, the ozone supply system 100 includes an oxygen source 120, an upstream mass flow controller (MFC) 121, an ozone generator 122, a pressure sensor 123, a flow control valve 124, and a shutoff valve 125, that are disposed in this order from an upstream end toward the downstream end of the common path 111. The supply path 110 branches into the three branching paths 112 at the branch point S located on a downstream end of the shutoff valve 125 of the common path 111. The ozone supply system 100 further includes a controller 160 that controls a configuration of the ozone supply system 100.

The oxygen source 120 of the ozone supply system 100 supplies oxygen (O₂) gas to the common path 111 on a downstream end of the oxygen source 120. The oxygen source 120 is not particularly limited, and a high-pressure tank capable of storing the oxygen gas, a compressor that inputs air and pressure feeds the oxygen gas, a pump, or the like may be used for the oxygen source 120. The ozone generator 122, located on a downstream end of the oxygen source 120, can be supplied with an oxygen gas containing nitrogen gas, and increase an ozone concentration of ozone by increasing a dissociation efficiency of oxygen molecules.

The upstream MFC 121 is an example of a flow controller (or flow rate controller). The upstream MFC 121 adjusts a flow rate of the oxygen gas supplied to the ozone generator 122, based on a command from the controller 160 indicating a target flow rate. The ozone supply system 100 can control a pressure applied to the ozone generator 122 from a primary side, by adjusting the flow rate of the oxygen gas by the upstream MFC 121.

The ozone generator 122 is a discharge-type device that generates ozone by performing a discharge with respect to the oxygen gas supplied from the upstream end. For example, the ozone generator 122 forms a discharge region between a pair of electrodes disposed in a parallel plate type arrangement or in a coaxial cylinder arrangement. The ozone generator 122 applies a high AC voltage between the pair of electrodes, while flowing the oxygen gas into the discharge region, thereby causing the discharge in the oxygen gas to generate the ozone. The ozone generator 122 can continuously generate the ozone having an approximately constant concentration, by continuously applying the voltage while flowing the oxygen gas. Then, the ozone generator 122 supplies the generated ozone-containing gas to the common path 111 on a secondary side (downstream end).

The pressure sensor 123 is provided in the common path 111 on the downstream end of the ozone generator 122, and detects a pressure of the ozone-containing gas flowing through the common path 111. The pressure sensor 123 is connected to the controller 160, and transmits a detected pressure value to the controller 160. The pressure sensor 123 provided in a vicinity of the downstream end of the ozone generator 122 can approximately detect the pressure inside the ozone generator 122.

The flow control valve 124 opens and closes flow paths (or channels) in the common path 111, and adjusts an amount of the ozone-containing gas supplied from the ozone generator 122 to the secondary side, by adjusting a gate opening under a control of the controller 160. In addition, the shutoff valve 125 shuts off the flow paths in the common path 111 in case of an emergency, such as a case where the pressure in the ozone generator 122 decreases to a predetermined value or less, a case where a trouble occurs, or the like, so as to shut off the supply of the ozone-containing gas.

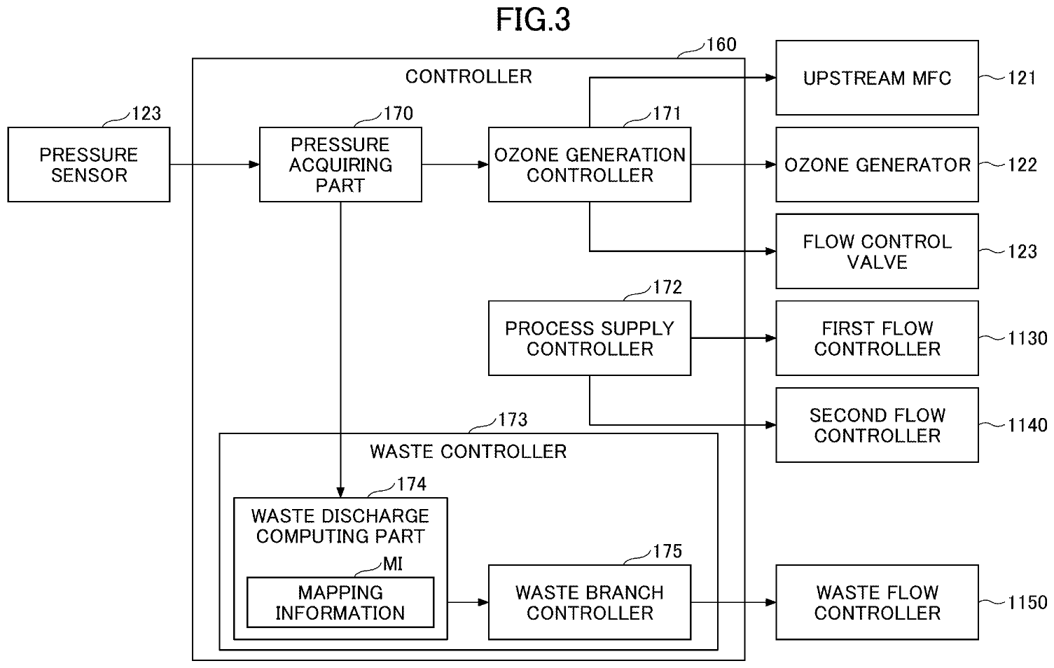

The first process branching path 113 of the branching path 112 includes a first process MFC 130 and a first on-off valve 131 that form an example of a first flow controller 1130 illustrated in FIG. 3. Similarly, the second process branching path 114 of the branching path 112 includes a second process MFC 140 and a second on-off valve 141 that form an example of a second flow controller 1140 illustrated in FIG. 3. The waste branching path 115 of the branching path 112 includes a waste MFC 150 and a third on-off valve 151 that form an example of a waste flow controller 1150 illustrated in FIG. 3.

Each of the first process MFC 130, the second process MFC 140, and the waste MFC 150 adjusts the flow rate of the ozone-containing gas in the corresponding branching path 112, based on the command from the controller 160 indicating the target flow rate. That is, the first process MFC 130 supplies a requested supplying amount of the ozone-containing gas to the first process chamber 10A, by maintaining the flow rate of the ozone-containing gas at the target flow rate. The second process MFC 140 supplies a requested supplying amount of the ozone-containing gas to the second process chamber 10B, by maintaining the flow rate of the ozone-containing gas at the target flow rate. For example, during processes of the first process chamber 10A and the second process chamber 10B, the ozone supply system 100 preferably sets the target flow rate of the first process MFC 130 and the target flow rate of the second process MFC 140 to the same value. Hence, the ozone supply system 100 can uniformly distribute the ozone-containing gas to each of the first process branching path 113 and the second process branching path 114.

The waste MFC 150 adjusts the flow rate of the ozone-containing gas discharged to the waste part 200, based on a waste flow rate (target flow rate) indicated by the command from the controller 160. The controller 160 of the ozone supply system 100 according to the present embodiment adjusts the flow rate of the ozone-containing gas to be discharged to the waste part 200, based on the pressure value detected by the pressure sensor 123. This control of the controller 160 associated with the adjustment of the waste flow rate will be described later in more detail.

In addition, the first on-off valve 131, the second on-off valve 141, and the third on-off valve 151 open and close the flow paths of the respective branching paths 112, to switch between supplying and stopping (or blocking) the supply of the ozone-containing gas. For example, when starting the supply of the ozone-containing gas to each process chamber 10, the ozone supply system 100 simultaneously opens the first on-off valve 131, the second on-off valve 141, and the third on-off valve 151 to allow the ozone-containing gas to flow. The opening and closing timings of the on-off valves 131, 141, and 151 may be different from one another. For example, when starting the supply of the ozone-containing gas, the third on-off valve 151 may be opened first, and the first on-off valve 131 and the second on-off valve 141 may be opened thereafter.

The controller 160 controls the upstream MFC 121, the ozone generator 122, the first process MFC 130, the second process MFC 140, the waste MFC 150, the first, second, and third on-off valves 131, 141, and 151, or the like, to supply the ozone-containing gas. The controller 160 may be a computer for control, including one or more processors 161, a memory 162, an input-output (I/O) interface (not illustrated), and an electronic circuit (not illustrated). The one or more processors 161 may be one of, or a combination of two or more selected from a central processing unit (CPU), a graphics processing unit (GPU), an application specific integrated circuit (ASIC), a field programmable gate array (FPGA), a circuit including a plurality of discrete semiconductors, or the like. The memory 162 includes a nonvolatile memory and a volatile memory, and forms a storage of the controller 160.

[Configuration of Substrate Processing Apparatus 1]

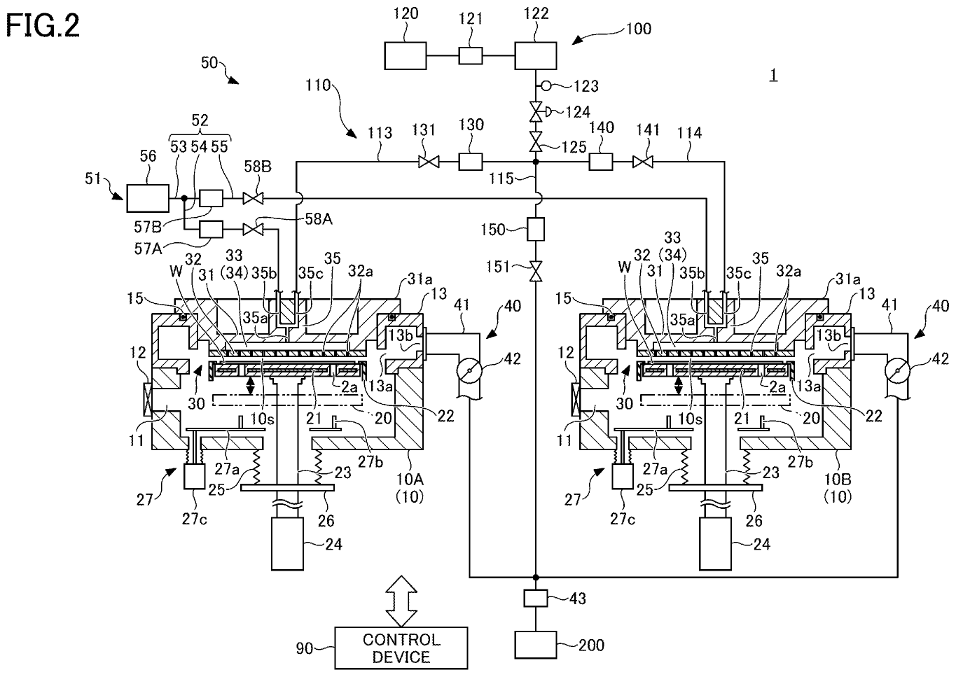

Next, a description will be given of an example of the substrate processing apparatus 1, including the ozone supply system 100 described above. As illustrated in FIG. 2, the substrate processing apparatus 1 using the ozone-containing gas may be a deposition apparatus that forms an oxide film on a surface of a substrate W by atomic layer deposition (ALD), for example. In addition, because the substrate processing apparatus 1 according to the present embodiment includes the two process chambers 10 (the first process chamber 10A and the second process chamber 10B), the substrate processing apparatus 1 may be used a so-called double-wafer deposition apparatus capable of processing two substrates W simultaneously or in parallel.

Examples of the substrate W on which the deposition process is performed include semiconductor substrates, such as a silicon wafer, a compound semiconductor wafer, or the like. Examples of the oxide film include high-dielectric films (high-k films), such as a HfO₂ film, a ZrO₂ film, a La₂O₃ film, and a Y₂O₃ film, or the like. In the present embodiment, an apparatus for depositing the HfO₂ film on the silicon wafer will be described as an example.

More particularly, the substrate processing apparatus 1 includes a susceptor 20, a shower head 30, an exhaust unit 40, and a gas supply unit 50, as components that are installed on or connected to each process chamber 10. The substrate processing apparatus 1 further includes a control device 90 configured to control each of the components of the substrate processing apparatus 1 to perform a deposition process.

Each process chamber 10 includes a processing space 10s in which the deposition process is performed on the substrate W. Each process chamber 10 is formed to an approximately cylindrical shape according to the planar shape of the substrate W to be accommodated therein. Moreover, each process chambers 10 includes a loading-unloading port 11 for loading and unloading the substrate W, and a gate valve 12 for opening and closing the loading-unloading port 11.

Further, the process chamber 10 includes an annular exhaust duct 13 at an upper portion thereof. The exhaust duct 13 has a slit 13a communicating with the processing space 10s along a circumferential direction of an inner peripheral surface thereof, and an exhaust port 13b located at a predetermined position of an outer peripheral surface thereof.

The susceptor 20 is made of nickel or the like, and is supported by a support member 23 inside each process chamber 10. The susceptor 20 is formed to a planar shape (perfect circular shape) corresponding to the substrate W, and horizontally supports the substrate W. In addition, the susceptor 20 includes therein a heater 21 for heating the substrate W that is placed on a placing surface (or upper surface) of the susceptor 20. The placing surface of the susceptor 20 is controlled by the heater 21 to a temperature in a range of 300° C. to 450° C., for example. Further, the susceptor 20 includes a cover member 22 made of ceramics, such as alumina or the like, so as to cover an outer peripheral region of the placing surface of the substrate W and a side surface of the susceptor 20.

The support member 23, that supports the susceptor 20, extends below the process chamber 10 from a center of a bottom surface of the susceptor 20, through a hole famed in a bottom wall of the process chamber 10, and a lower end of the support member 23 is connected to an elevator mechanism 24. The susceptor 20 is raised and lowered by the elevator mechanism 24, via the support member 23. More particularly, the elevator mechanism 24 moves the susceptor 20 between a processing position where the deposition process is performed on the substrate W, and a transport position where the substrate W can be transported below the processing position. In addition, a bellows 25 that expands and contracts according to an elevator operation (or raising and lowering) of the susceptor 20, and a flange 26 that closes a lower end of the bellows 25, are provided below the process chamber 10 along a vertical direction.

Each process chamber 10 includes a substrate elevator unit 27 disposed on the bottom wall thereof. The substrate elevator unit 27 includes an elevator plate 27a, a plurality of support pins 27b (for example, three support pins 27b in this example) protruding upward from the elevator plate 27a, and a pin raising and lowering mechanism 27c for raising and lowering the elevator plate 27a. When loading the substrate W into the process chamber 10, the substrate elevator unit 27 raises each support pin 27b with respect to the substrate W transported by a substrate transport mechanism (not illustrated) to receive the substrate W, and thereafter lowers each support pin 27b so as to place the substrate W on the susceptor 20 at the processing position. On the other hand, when unloading the substrate W from the process chamber 10, the substrate elevator unit 27 raises each support pin 27b to raise the substrate W above the susceptor 20 at the processing position, and transfers the substrate W to the substrate transport mechanism that entered the process chamber 10.

The shower head 30 is formed of aluminum, for example, and is provided on each process chamber 10 at an upper end along the vertical direction, so as to oppose the susceptor 20. The shower head 30 includes a main body 31, and a shower plate 32.

The main body 31 is formed to an approximately cylindrical shape, and has a recess 34, that serves as a gas diffusion space 33, located at a center on a lower end along the vertical direction. A flange 31a, that protrudes radially outward and engages the exhaust duct 13, is provided on an upper end of an outer edge portion of the main body 31. A gap between the flange 31a and the exhaust duct 13 is sealed airtight by a sealer 15. In addition, the main body 31 includes a gas introducing portion 35 protruding upward in the vertical direction at a center of an upper portion thereof. The gas introducing portion 35 includes a lower gas flow path 35a connected to the gas diffusion space 33, and two upper gas flow paths 35b and 35c connected to the lower gas flow path 35a.

The shower plate 32 is attached to the lower end of the main body 31 along the vertical direction, so as to cover the recess 34. The gas diffusion space 33 is defined by the recess 34 and the shower plate 32. The shower plate 32 has a plurality of gas discharge holes 32a through which the gas is discharged from the gas diffusion space 33.

The exhaust unit 40 includes an exhaust path 41 connected to the exhaust port 13b of the exhaust duct 13 of each process chamber 10. The exhaust path 41 branches into two on an upstream end, so as to discharge the gas in the first process chamber 10A and the gas in the second process chamber 10B. An automatic pressure control (APC) valve 42 for adjusting the pressure inside each process chamber 10 is provided at each branching portion of the exhaust path 41. In addition, a vacuum pump 43, and a waste part 200 for processing the exhaust gas, are provided at a merging portion of the exhaust path 41. During the deposition process, the substrate processing apparatus 1 operates the vacuum pump 43 to suck the gas inside each process chamber 10. Accordingly, the gas inside each process chamber 10 is discharged from the exhaust duct 13 to the waste part 200 through the exhaust path 41.

The gas supply unit 50 includes a source gas supply system 51 for supplying a source gas, and the ozone supply system 100 described above.

The source gas supply system 51 includes a source gas supply path 52 connected to the upper gas flow paths 35b. In addition, in the source gas supply system 51, the source gas supply path 52 branches to supply the source gas to the first process chamber 10A and the second process chamber 10B. In other words, the source gas supply path 52 includes a common path 53, a first process branching path 54 extending from the common path 53 to the first process chamber 10A, and a second process branching path 55 extending from the common path 53 to the second process chamber 10B.

The source gas supply system 51 includes a source gas source 56 on the upstream end of the common path 111. The source gas supplied by the source gas source 56 is not particularly limited, as long as a metal-containing film can be formed by the deposition process, and may be an organic compound or an inorganic compound. In an example where a HfO₂ film is deposited, for example, an organohafnium compound, such as tetrakis(dimethylamino) hafnium (Hf[N(CH₃)₂]4: TDMAH), or tris(dimethylamino) cyclopentadienyl hafnium, hafnium chloride (HfCl₄), or the like may be used.

The first process branching path 54 and the second process branching path 55 are provided with flow controllers (or flow rate controllers) 57A and 57B, such as mass flow controllers or the like, and on-off valves 58A and 58B, respectively, in this order from the upstream end to the downstream end. The control device 90 of the substrate processing apparatus 1 controls the flow controller 57A and the on-off valve 58A of the first process branching path 54, to switch between supplying and stopping (or blocking) the supply of the source gas, and to adjust the flow rate of the source gas supplied to the first process chamber 10A. Similarly, the control device 90 of the substrate processing apparatus 1 controls the flow controller 57B and the on-off valve 58B of the second process branching path 55, to switch between supplying and stopping (or blocking) the supply of the source gas, and to adjust the flow rate of the source gas supplied to the second process chamber 10B. The gas supplying unit 50 may connect a purge gas supply path (not illustrated) for supplying a purge gas, such as a nitrogen (N₂) gas or the like, for example, to the source gas supply path 52. The purge gas may be used as a counter flow during the deposition process.

As described above, the ozone supply system 100 includes the first process branching path 113, the second process branching path 114, and the waste branching path 115. The ozone supply system 100 supplies the ozone-containing gas to the first process chamber 10A through the first process branching path 113, and supplies the ozone-containing gas to the second process chamber 10B through the second process branching path 114. In addition, the waste branching path 115 of the ozone supply system 100 is connected to the exhaust path 41 (upstream end of the vacuum pump 43) of the substrate processing apparatus 1. Accordingly, the substrate processing apparatus 1 can directly discharge the ozone-containing gas to the common waste part 200, without passing through each process chamber 10, by supplying the ozone-containing gas through the waste branching path 115.

The control device 90 controls the susceptor 20, the exhaust unit 40, the source gas supply system 51, or the like, to perform the deposition process in the process chamber 10. The control device 90 may be a computer for control, including one or more processors (not illustrated), a memory (not illustrated), an I/O interface (not illustrated), and an electronic circuit (not illustrated). The one or more processors may be one of, or a combination of two or more selected from a CPU, a GPU, an ASIC, an FPGA, a circuit including a plurality of discrete semiconductors, or the like. The memory includes a nonvolatile memory and a volatile memory, and forms a storage of the control device 90. The memory stores one or more programs for controlling the deposition process, and one or more recipes to be executed by the deposition process. The one or more processors perform the control, by reading the program, the recipe, or the stored in the memory.

At an appropriate timing during the deposition process, the control device 90 outputs a supply command, a supply end command, or the like to the controller 160 of the ozone supply system 100, in order to supply the ozone-containing gas to the first process chamber 10A and the second process chamber 10B. The supply command includes the target flow rate of the ozone-containing gas, for example, in addition to command information related to starting the supply. Accordingly, the controller 160 controls each component to supply the ozone-containing gas in accordance with the target flow rate to the first process chamber 10A and the second process chamber 10B. Although the controller 160 of the ozone supply system 100 and the control device 90 of the substrate processing apparatus 1 are provided separately in the present embodiment, the present invention is not limited to such a configuration. The control device 90 may include the functions of the controller 160, such as the function of controlling the supply of the ozone-containing gas.

[Controller 160 of Ozone Supply System 100]

In the controller 160 of the ozone supply system 100, the processor 161 reads and executes the program stored in the memory 162, thereby configuring functional blocks for supplying the ozone-containing gas, as illustrated in FIG. 3. More particularly, a pressure acquiring part 170, an ozone generation controller 171, a process supply controller 172, and a waste controller 173 are formed in the controller 160.

The pressure acquiring part 170 constantly acquires the pressure value detected by the pressure sensor 123 provided in the supply path 110, temporarily stores the pressure value in the memory 162, and outputs the pressure value to the ozone generation controller 171, the waste controller 173, or the like.

The ozone generation controller 171 controls the upstream MFC 121, the ozone generator 122, the flow control valve 124, or the like, to supply the oxygen gas to the ozone generator 122 and generate the ozone-containing gas in the ozone generator 122. In addition, when generating the ozone-containing gas, the ozone generation controller 171 controls the upstream MFC 121 and the flow control valve 124, based on the pressure value detected by the pressure sensor 123, to thereby stabilize the concentration of the ozone-containing gas generated by the ozone generator 122.

The process supply controller 172 controls the first flow controller 1130 (the first process MFC 130 and the first on-off valve 131), and the second flow controller 1140 (the second process MFC 140 and the second on-off valve 141), based on the target flow rate acquired from the control device 90. Accordingly, the process supply controller 172 controls the supplying and stopping of the ozone-containing gas to each process chamber 10, and adjusts the supplying amount (or flow rate) to each process chamber 10. In the present embodiment, the process supply controller 172 simultaneously supplies the ozone-containing gas to the first process chamber 10A and the second process chamber 10B, and supplies the same supplying amount of ozone gas. However, the ozone supply system 100 may perform the supply of the ozone-containing gas to the first process chamber 10A and the supply of the ozone-containing gas to the second process chamber 10B at different timings. For example, the ozone supply system 100 may supply the ozone-containing gas to the first process chamber 10B in a state where the supply the ozone-containing gas to the second process chamber 10A is stopped.

The waste controller 173 controls the flow rate of the ozone-containing gas flowing through the waste branching path 115. A waste discharge computing part 174 and a waste branch controller 175 are famed in the waste controller 173. The waste discharge computing part 174 computes the flow rate of the ozone-containing gas for controlling the waste MFC 150, based on the pressure value detected by the pressure sensor 123 and acquired by the pressure acquiring part 170. For example, the waste discharge computing part 174 stores mapping information MI or a function representing a correspondence between the pressure value and the flow rate of the ozone-containing gas in the memory 162, and upon receiving the pressure value, refers to the mapping information MI or the function stored in the memory 162 to extract the flow rate corresponding to the pressure value.

The waste branch controller 175 controls the waste MFC 150 and the third on-off valve 151, based on the flow rate of the ozone-containing gas computed by the waste discharge computing part 174, to thereby control the discharging and stopping the discharge of the ozone-containing gas to the waste part 200 and the waste flow rate. That is, when supplying the ozone-containing gas to the first process chamber 10A and the second process chamber 10B, the ozone supply system 100 adjusts the flow rate of the ozone-containing gas discharged to the waste part 200. Hereinafter, the significance of controlling the flow rate of the ozone-containing gas in the waste branching path 115 will be described.

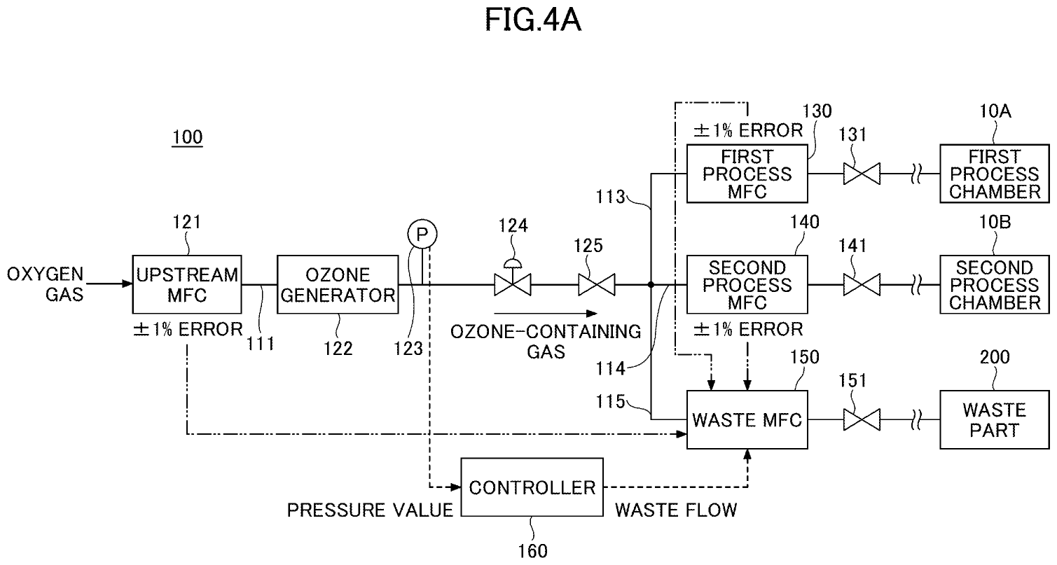

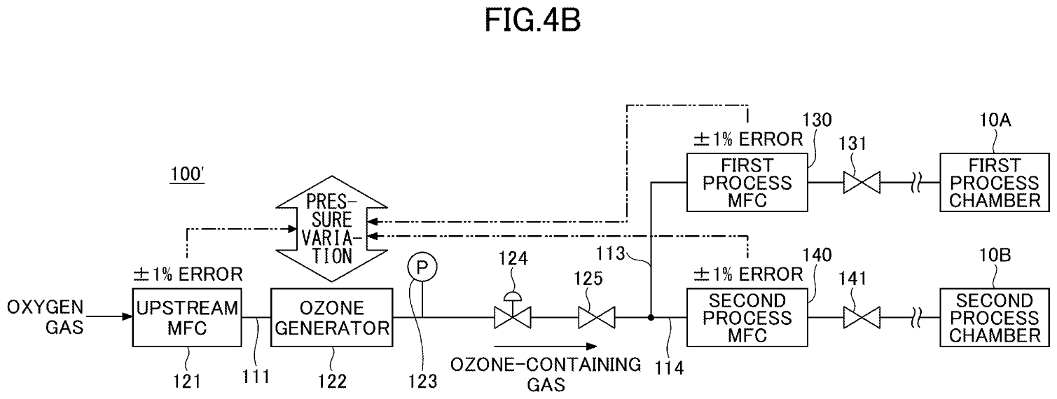

As illustrated in FIG. 4A and FIG. 4B, each of the upstream MFC 121 of the common path 111, the first process MFC 130 of the first process branching path 113, and the second process MFC 140 of the second process branching path 114 adjusts the flow rate of the gas flowing therethrough. However, in each MFC, an error in the flow rate with respect to the target value generally occurs in a range of approximately ±1%. For example, in a ozone supply system 100′ according to a reference example illustrated in FIG. 4B having no waste branching path 115, suppose that an error of −1% occurs in the upstream MFC 121, and an error of +1% occurs in each of the first process MFC 130 and the second process MFC 140. In this case, in the ozone generator 122 of the ozone supply system 100′, while the flow rate of the oxygen gas flowing into the ozone generator 122 is small, the flow rate of the ozone-containing gas supplied from the ozone generator 122 becomes large. For this reason, the pressure in the ozone generator 122 decreases in the ozone supply system 100′.

When a pressure drop in the ozone generator 122 caused by the errors becomes large, the ozone supply system 100′ performs a control to vary the supplying amount of the oxygen gas and the supplying amount of ozone-containing gas by the upstream MFC 121 and the flow control valve 124. As a result, the concentration of the ozone becomes unstable. In particular, when supplying the ozone-containing gas to a plurality of process chambers 10, an error multiple times larger than that when supplying the ozone-containing gas to a single process chamber 10 may occur, and a pressure fluctuation in the ozone generator 122 is likely to increase. In some cases, it may be determined that there is an abnormality in the generation of the ozone-containing gas, and the ozone supply system 100′ may be stopped.

On the other hand, as illustrated in FIG. 4A, the ozone supply system 100 according to the present embodiment includes the waste branching path 115 in the supply path 110. That is, in the ozone supply system 100, a supernatant gas of the ozone-containing gas in the ozone generator 122 is caused to flow through the waste branching path 115, so as to discard a portion of the ozone-containing gas through the waste branching path 115. As a result, a pressure fluctuation caused by variations in the flow rates of the other paths can be compensated by a variation in the flow rate of the waste branching path 115.

More particularly, the controller 160 adjusts the flow rate of the ozone-containing gas of the waste MFC 121, so as to absorb the errors in the upstream MFC 130, the first process MFC 140, and the second process MFC 150. As a result, the ozone supply system 100 can control the pressure value detected by the pressure sensor 123 to become constant at the target pressure, without having to perform adjustments by the upstream MFC 121 and the flow control valve 124.

The waste flow rate of the waste MFC 150 may be set to be smaller than the flow rate of the first process MFC 130 and the flow rate of the second process MFC 140, or may be set to be the same as the flow rate of the first process MFC 130 and the flow rate of the second process MFC 140. When the waste flow rate is small, the amount of the ozone-containing gas that does not flow through the process chamber 10 can be reduced. However, the waste flow rate is set to a value larger than an amount including all of the error of the upstream MFC 121, the error of the first process MFC 130, and the error of the second process MFC 140. As an example, in a case where the error of the upstream MFC 121 is ±30 ccm, the error of the first process MFC 130 is ±10 ccm, and the error of the second process MFC 140 is ±10 ccm, the waste flow rate of the waste MFC 150 may preferably be set to a value larger than 50 ccm.

For example, in a case where the flow rate of the oxygen gas decreases in the upstream MFC 121 decreases, and the flow rate of the ozone-containing gas increases in each of the first process MFC 130 and the second process MFC 140, the pressure in the ozone generator 122 becomes lower than the target pressure. For this reason, the controller 160 controls the waste MFC 150 so that the amount of the ozone-containing gas flowing through the waste branching path 115 is reduced, based on the pressure value detected by the pressure sensor 123. As a result, the flow rate of the ozone-containing gas flowing through the waste branching path 115 decreases, and the pressure in the ozone generator 122 increases. In other words, the ozone supply system 100 can return the pressure in the ozone generator 122 to the target pressure without adjusting the flow rate of the first process branching path 113 and the flow rate of the second process branching path 114.

On the other hand, in a case where the flow rate of the oxygen gas increases in the upstream MFC 121, and the flow rate of the ozone-containing gas decreases in each of the first process MFC 130 and the second process MFC 140, the pressure in the ozone generator 122 becomes higher than the target pressure. For this reason, the controller 160 controls the waste MFC 150, so that the amount of the ozone-containing gas flowing through the waste branching path 115 increases, based on the pressure value detected by the pressure sensor 123. As a result, the flow rate of the ozone-containing gas flowing through the waste branching path 115 increases, and the pressure in the ozone generator 122 decreases. In other words, the ozone supply system 100 can return the pressure in the ozone generator 122 to the target pressure, without adjusting the flow rate of the first process branching path 113 and the flow rate of the second process branching path 114.

[Ozone Supply Method]

The ozone supply system 100 and the substrate processing apparatus 1 according to the present embodiment are basically configured as described above. Hereinafter, an operation (ozone supply method) of the ozone supply system 100 will be described.

When performing a substrate processing of the substrate processing apparatus 1, the controller 160 of the ozone supply system 100 receives the supply command from the control device 90 (step S1). Accordingly, the controller 160 starts the generation of the ozone-containing gas. First, the ozone generation controller 171 controls the upstream MFC 121, the ozone generator 122, the flow control valve 124, or the like to supply the oxygen gas to the ozone generator 122, and generates the ozone by performing a discharge with respect to the oxygen gas in the ozone generator 122 (step S2).

Then, the process supply controller 172 starts supplying the ozone-containing gas to each of the process chambers 10 (step S3). More particularly, the process supply controller 172 operates the first process MFC 130 and the second process MFC 140, so that the flow rate becomes the target flow rate included in the supply command. Accordingly, the ozone-containing gas generated by the ozone generator 122 is supplied to the first process chamber 10A through the first process branching path 113, and is also supplied to the second process chamber 10B through the second process branching path 114.

Further, as the ozone-containing gas is supplied to each process chamber 10, the waste controller 173 starts the flow of the ozone-containing gas from the waste branching path 115 with respect to the waste part 200 (step S4). That is, the waste controller 173 opens the third on-off valve 151, and operates the waste MFC 150, to cause the ozone-containing gas to flow through the waste branching path 115.

When supplying the ozone-containing gas to the secondary side, the pressure acquiring part 170 of the controller 160 continuously acquires the pressure value of the ozone-containing gas supplied from the ozone generator 122, detected by the pressure sensor 123 (step S5).

After the start of supplying the ozone-containing gas, the process supply controller 172 adjusts the flow rate of the first process MFC 130 and the flow rate of the second process MFC 140 to the same amount, and continuously supplies the ozone-containing gas to the first process chamber 10A and the second process chamber 10B (step S6).

On the other hand, while the ozone-containing gas is supplied to each process chamber 10, the waste controller 173 controls the waste MFC 150 to adjust the flow rate of the waste branching path 115, based on the pressure detected by the pressure sensors 123 and acquired by the pressure acquiring part 170 (step S7). More specifically, the waste discharge computing part 174 computes the flow rate of the ozone-containing gas in the waste branching path 115, based on the pressure value detected by the pressure sensor 123. In addition, the waste branch controller 175 transmits a flow rate adjustment command to the waste MFC 150, according to a discarding flow rate computed by the waste discharge computing part 174. Thus, the waste MFC 150 adjusts the flow rate of the ozone-containing gas discharged from the waste branching path 115 to the waste part 200.

Then, the controller 160 determines whether or not to end the supply of the ozone-containing gas, based on a supply stop command from the control device 90, a predetermined processing period (or time), or the like (step S8). In a case where it is determined that the supply of the ozone-containing gas is to be continued (NO in step S8), the process returns to step S6, and the similar processes are repeated. On the other hand, in a case where it is determined that the supply of the ozone-containing gas is to be ended (YES in step S8), the controller 160 performs an end process to stop the supply of the ozone-containing gas. For example, in the end process, the controller 160 performs process including stopping the supply of the oxygen gas, stopping the ozone generator 122, blocking each branching path 112, or the like.

As described above, the ozone supply system 100 can control the pressure in ozone generator 122 constant, by discharging the ozone-containing gas to the waste branching path 115 connected to the waste part 200. Accordingly, the ozone supply system 100 can stably generate the ozone-containing gas having a constant concentration in the ozone generator 122, and can satisfactorily supply the generated ozone-containing gas to each process chamber 10.

In addition, as an example, even in a case where the supply of the ozone-containing gas to the second process chamber 10B is stopped, the ozone supply system 100 can divert the ozone-containing gas, stopped from being supplied to the second process chamber 10B, to the waste branching path 115. For this reason, the flow rate of the ozone-containing gas supplied to the first process chamber 10A does not need to be varied. Hence, even when a trouble or the like occurs, for example, the substrate processing apparatus 1 can avoid wasting both the substrates W being processed in the first process chamber 10A and the second process chamber 10B.

The ozone supply system 100 is not limited to the configuration described above, and various modifications may be made. For example, the number of supply targets to which the ozone supply system 100 supplies the ozone-containing gas is not limited to two, and may be three or more.

Further, the ozone supply system 100 is not limited to supplying the ozone-containing gas to the plurality of process chambers 10, and may be configured to supply the ozone-containing gas to a single process chamber 10. Even in this latter case, the ozone supply system 100 may have a configuration including the two branching paths 112, where one branching path 112 is connected to the single process chamber 10, and the other branching path 112 is connected to the waste part 200. Alternatively, the ozone supply system 100 may have a configuration including three or more branching paths 112, where one branching path 112 is connected to the waste part 200, and the other branching paths 112 are connected to the single process chamber 10.

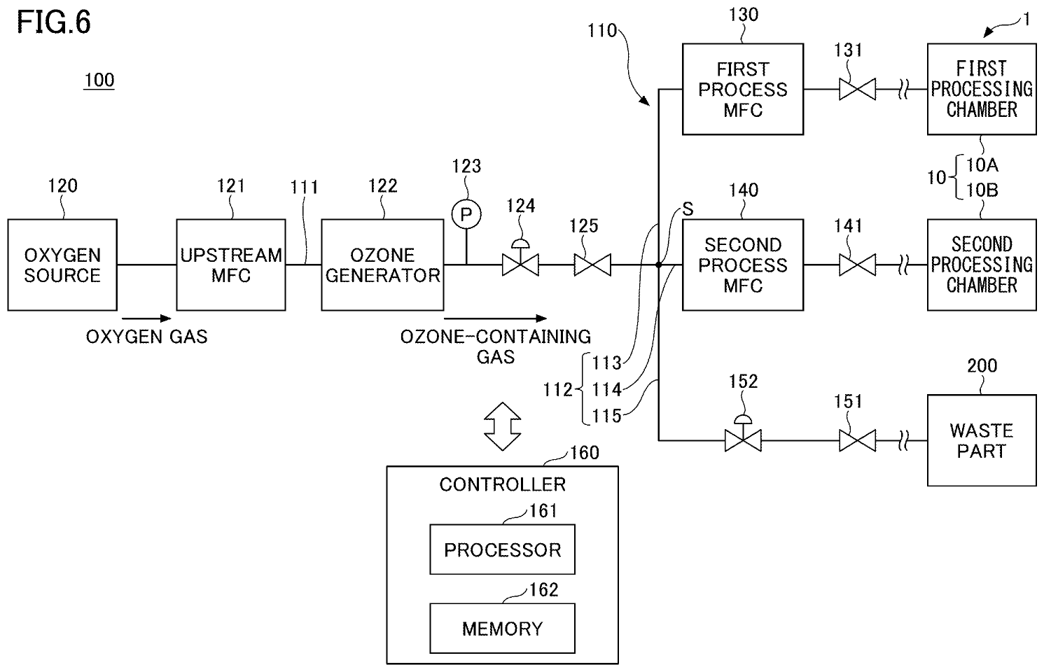

Further, as illustrated in FIG. 6, the ozone supply system 100 may include a waste flow control valve 152 capable of adjusting a gate opening of the flow path in the waste branching path 115, as a waste flow controller in place of the waste MFC 150, for example. The waste flow control valve 152 can easily adjust the flow rate of the ozone-containing gas flowing through the waste branching path 115. In other words, the ozone supply system 100 may employ various configurations capable of adjusting the flow rate of the ozone-containing gas flowing through the waste branching path 115, as the waste flow controller.

The technical concept and effects of the present disclosure described in the embodiments described above, will now be described in the following.

The ozone supply system 100 according to a first aspect of the present disclosure includes the supply path 110 configured to supply the gas, and the ozone generator 122 provided in the supply path 110, configured to generate the ozone using the oxygen gas supplied from the upstream end of the supply path 110, and supply the ozone-containing gas containing the ozone to the downstream end. The supply path 110 branches into the plurality of branching paths 112 on the downstream end of the ozone generator 122, and at least one branching path 112 of the plurality of branching paths 112 is the process branching path (the first process branching path 113, the second process branching path 114) connected to the processing part (the process chamber 10) that uses the ozone-containing gas. The remaining branching path 112, other than the at least one branching path 112, of the plurality of branching paths 112, is the waste branching path 115 connected to the waste part 200 that discharges the ozone-containing gas. The waste branching path 115 includes the waste flow controller 1150 (the waste MFC 150 and the waste flow control valve 152) configured to adjust the flow rate of the ozone-containing gas.

According to the configuration described above, because the ozone supply system 100 supplies a portion of the ozone-containing gas supplied from the ozone generator 122 to the waste branching path 115, it is possible to compensate for the variations in the pressures in the ozone generator 122 and the supply path 110 by the variation in the flow rate of the waste branching path 115. That is, the ozone supply system 100 can stabilize the pressure in the ozone generator 122 on the upstream end of the plurality of branching paths 112, by adjusting the flow rate of the ozone-containing gas in the waste branching path 115 by the waste MFC 150 and the waste flow control valve 152. As a result, the ozone generator 122 can stably generate the ozone.

Moreover, the pressure sensor 123 is provided in the supply path 110 between the ozone generator 122 and the branch point S of the plurality of branching paths 112, and the controller 160 controls the adjustment of the flow rate of the ozone-containing gas by the waste flow controller 1150 (the waste MFC 150 and the waste flow control valve 152), based on the pressure value detected by the pressure sensor 123. Accordingly, the ozone supply system 100 can discharge the ozone-containing gas from the waste branching path 115 at an appropriate flow rate, based on the pressure value detected by the pressure sensor 123.

In addition, the controller 160 controls the waste flow controller 1150 (the waste MFC 150 and the waste flow control valve 152), so that the pressure value detected by the pressure sensor 123 becomes constant at the target pressure. As a result, in the ozone supply system 100, the pressure in the ozone generator 122 becomes constant, and it is possible to stabilize the concentration or the like of the generated ozone.

Further, the controller 160 controls the waste flow controller 1150 (the waste MFC 150 and the waste flow control valve 152) to reduce the flow rate of the ozone-containing gas when the pressure is lower than the target pressure, and controls the waste flow controller 1150 to increase the flow rate of the ozone-containing gas when the pressure is higher than the target pressure. Thus, the ozone supply system 100 can easily and accurately control the pressure in the ozone generator 122 constant.

In addition, the supply path 110 includes the plurality of process branching paths (the first process branching path 113 and the second process branching path 114) connected to the plurality of processing parts (the first process chamber 10A and the second process chamber 10B), respectively, and the process flow controller 1130 or 1140 (the first process MFC 130 or the second process MFC 140) provided in each of the plurality of process branching paths to adjust the flow rate of the ozone-containing gas supplied to the plurality of processing parts. By supplying the ozone-containing gas to the plurality of processing parts in this manner, the ozone supply system 100 can promote reduction of both manufacturing cost and footprint. Moreover, this configuration can stabilize the generation of the ozone-containing gas in the ozone generator 122, by the waste branching path 115 and the waste flow controller.

Further, the plurality of process flow controllers 1130 and 1140 (the first process MFC 130 and the second process MFC 140) adjust the flow rates of the ozone-containing gas to be equal to one another. Accordingly, the ozone supply system 100 can stably perform the same process, using the ozone-containing gas supplied to each of the plurality of processing parts (the first process chamber 10A and the second process chamber 10B).

Moreover, the waste flow controller 1150 may be a mass flow controller (waste MFC 150). Thus, the ozone supply system 100 can accurately adjust the flow rate of the ozone-containing gas flowing through the waste branching path 115.

The waste flow rate controller 1150 may be a flow control valve (the waste flow control valve 152) that adjusts the gate opening of the flow path of the waste branching path 115. Even in this case, the ozone supply system 100 can easily adjust the flow rate of the ozone-containing gas flowing through the waste branching path 115.

The substrate processing apparatus 1 according to a second aspect of the present disclosure includes the process chamber 10 configured to process the substrate W, and the ozone supply system 100 configured to supply the ozone-containing gas to the process chamber 10. The ozone supply system 100 includes the supply path 110 configured to supply the gas, and the ozone generator 122 provided in the supply path 110, configured to generate the ozone using the oxygen gas supplied from the upstream end of the supply path 110, and supply the ozone-containing gas to the downstream end of the ozone generator 122. The supply path 110 branches into the plurality of branching paths 112 on the downstream end of the ozone generator 122. At least one branching path 112 of the plurality of branching paths 112 is the process branching path (first process branching path 113, second process branching path 114) connected to the process chamber 10. The remaining branching path 112, other than the at least one branching path 112, of the plurality of branching paths 112, is the waste branching path 115 connected to the waste part 200 that discharges the ozone-containing gas. The waste branching path 115 includes the waste flow controller 1150 (the waste MFC 150 and the waste flow control valve 152) configured to adjust the flow rate of the ozone-containing gas.

The ozone supply method according to a third aspect of the present disclosure is to be implemented in the ozone supply system 100 including the supply path 110 configured to supply the gas, and the ozone generator 122 provided in the supply path 110, configured to generate the ozone using the oxygen gas supplied from the upstream end of the supply path 110, and supply the ozone-containing gas containing the ozone to the downstream end of the ozone generator 122. The supply path 110 branches into the plurality of branching paths 112 on the downstream end of the ozone generator 122. The ozone supply method includes the steps of supplying the ozone-containing gas to the processing part (the first process chamber 10) through the process branching path (the first process branching path 113, the second process branching path 114) that is at least one branching path of the plurality of branching paths 112, and discharging the ozone-containing gas through the waste branching path 115 that is a remaining branching path 112, other than the at least one branching path, of the plurality of branching paths 112, and controlling a flow rate of the ozone-containing gas by the waste flow controller 1150 (the waste MFC 150 and the waste flow control valve 152) during the discharging.

The second aspect and the third aspect of the present disclosure can also stabilize the generation of the ozone in the ozone generator 122.

The ozone supply system 100, the substrate processing apparatus 1, and the ozone supply method according to the embodiments disclosed herein have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

The substrate processing apparatus 1 according to the present disclosure is not limited to the ALD apparatus, and may be applied to various types of apparatuses configured to perform depositions using capacitively coupled plasma (CCP), inductively coupled plasma (ICP), radial line slot antenna (RLSA), electron cyclotron resonance plasma (ECR), helicon wave plasma (HWP), or the like. Further, the ozone supply system 100 can of course be applied to various apparatuses using the ozone-containing gas.

According to one aspect of the present disclosure, it is possible to stabilize generation of ozone in the ozone generator.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An ozone supply system comprising:
a supply path configured to supply a gas; and
an ozone generator, provided in the supply path, and configured to generate ozone using oxygen gas supplied from an upstream end of the supply path, and supply an ozone-containing gas containing the ozone to a downstream end of the ozone generator, wherein
the supply path branches into a plurality of branching paths on the downstream end of the ozone generator,
at least one branching path of the plurality of branching paths is a process branching path connected to a processing part that uses the ozone-containing gas,
a remaining branching path, other than the at least one branching path, of the plurality of branching paths is a waste branching path connected to a waste part configured to discharge the ozone-containing gas, and
the waste branching path includes a waste flow controller configured to control a flow rate of the ozone-containing gas.

2. The ozone supply system as claimed in claim 1, further comprising:
a pressure sensor, provided in the supply path between the ozone generator and a branch point of the plurality of branching paths; and
a controller configured to control the flow rate of the ozone-containing gas by the waste flow controller, based on a pressure value detected by the pressure sensor.

3. The ozone supply system as claimed in claim 2, wherein the controller controls the waste flow controller, so that the pressure value detected by the pressure sensor becomes a constant target pressure.

4. The ozone supply system as claimed in claim 3, wherein the controller controls the waste flow controller to decrease the flow rate of the ozone-containing gas when the pressure value is lower than the target pressure, and controls the waste flow controller to increase the flow rate of the ozone-containing gas when the pressure value is higher than the target pressure.

5. The ozone supply system as claimed in claim 1, wherein the supply path includes
a plurality of process branching paths connected to a plurality of processing parts, respectively, and
a plurality of process flow controllers, provided in the plurality of process branching paths, and configured to control flow rates of the ozone-containing gas supplied to the plurality of processing parts, respectively.

6. The ozone supply system as claimed in claim 5, wherein the plurality of process flow controllers control the flow rates of the ozone-containing gas to be equal to one another.

7. The ozone supply system as claimed in claim 1, wherein the waste flow controller is a mass flow controller.

8. The ozone supply system as claimed in claim 1, wherein the waste flow controller is a flow control valve configured to adjust a gate opening of a flow path of the waste branching path.

9. A substrate processing apparatus comprising:
a process chamber configured to process a substrate; and
an ozone supply system configured to supply an ozone-containing gas containing ozone into the process chamber, wherein
the ozone supply system includes
a supply path configured to supply a gas, and
an ozone generator, provided in the supply path, and configured to generate ozone using oxygen gas supplied from an upstream end of the supply path, and supply an ozone-containing gas containing the ozone to a downstream end of the ozone generator, wherein
the supply path branches into a plurality of branching paths on a downstream end of the ozone generator,
at least one branching path of the plurality of branching paths is a process branching path connected to the process chamber,
a remaining branching path, other than the at least one branching path, of the plurality of branching paths is a waste branching path connected to a waste part configured to discharge the ozone-containing gas, and
the waste branching path includes a waste flow controller configured to control a flow rate of the ozone-containing gas.

10. An ozone supply method to be implemented in an ozone supply system that includes a supply path configured to supply a gas, and an ozone generator, provided in the supply path, and configured to generate ozone using oxygen gas supplied from an upstream end of the supply path, and supply an ozone-containing gas containing the ozone to a downstream end of the ozone generator, wherein the supply path branches into a plurality of branching paths on the downstream end of the ozone generator, the ozone supply method comprising:
supplying the ozone-containing gas to a processing part through a process branching path that is at least one branching path of the plurality of branching paths; and
discharging the ozone-containing gas through a waste branching path that is a remaining branching path, other than the at least one branching path, of the plurality of branching paths, and controlling a flow rate of the ozone-containing gas by a waste flow controller during the discharging.
